(19) United States
(12) Patent Application Publication
(10) Pub. No.: US 2011/0100409 A1
(43) Pub. Date: May 5, 2011

(54) THERMOELECTRIC NANO-COMPOSITE, AND THERMOELECTRIC MODULE AND THERMOELECTRIC APPARATUS INCLUDING THE THERMOELECTRIC NANO-COMPOSITE

(75) Inventors: Hyun-sik KIM, Seoul (KR); Kyu-hyoung LEE, Yongin-si (KR); Sang-mock LEE, Yongin-si (KR); Eun-sung LEE, Yongin-si (KR); Sang-soo JEE, Hwaseong-si (KR); Xiangshu LI, Yongin-si (KR)

(73) Assignee: SAMSUNG ELECTRONICS CO., LTD., Suwon-si (KR)

(21) Appl. No.: 12/939,689

(22) Filed: Nov. 4, 2010

(30) Foreign Application Priority Data
Nov. 5, 2009 (KR) 10-2009-0106652

(51) Int. Cl. H01L 35/14; H01L 35/16; H01L 35/30; B22F 3/14; B22F 1/00

(52) U.S. Cl. 136/205; 136/238; 136/239; 252/62.3 T; 419/48; 419/30; 136/201

(57) ABSTRACT

A thermoelectric nano-composite including a thermoelectric matrix; a nano-metal particle; and a nano-thermoelectric material represented by Formula 1:

AₓM_{y}B_{z} Formula 1

wherein A includes at least one element of indium, bismuth, or antimony, B includes at least one element of tellurium or selenium (Se), M includes at least one element of gallium, thallium, lead, rubidium, sodium, or lithium, x is greater than 0 and less than or equal to about 4, y is greater than 0 and less than or equal to about 4, and z is greater than 0 and less than or equal to about 3.

### CROSS-REFERENCE TO RELATED APPLICATIONS

This application claims priority to Korean Patent Application No. 10-2009-0106652, filed on Nov. 5, 2009, and all the benefits accruing therefrom under 35 U.S.C. §119, the content of which in its entirety is herein incorporated by reference.

### BACKGROUND

1. Field

The present disclosure relates to thermoelectric nano-composite having an excellent figure-of-merit, and a thermoelectric module and a thermoelectric apparatus including the thermoelectric nano-composite, and more particularly, to chalcogenide thermoelectric nano-composite having a high Seebeck coefficient, high electrical conductivity, and low thermal conductivity, and an thermoelectric module and a thermoelectric apparatus including the chalcogenide thermoelectric nano-composite.

2. Description of the Related Art

Thermoelectric materials are generally used in active cooling and waste heat power generation based on the Peltier effect and the Seebeck effect. The Peltier effect is a phenomenon wherein, as illustrated in FIG. 1, holes of a p-type material 100 and electrons of an n-type material 110 move when a direct current (“DC”) voltage is applied to the n-type and p-type materials, thus exothermic and endothermic reactions occur at opposite ends of the n-type and p-type materials. The Seebeck effect is a phenomenon in which, as illustrated in FIG. 2, holes of a p-type material 100 and electrons of an n-type material 110 move when heat is provided by an external heat source to the n-type and p-type materials, and thus a current flows in an element 120 which is electrically connected to the n-type and p-type materials, thereby generating electrical power.

Active cooling using a thermoelectric material improves the thermal stability of a device, does not produce vibration or noise, and does not require a separate condenser or a halocarbon refrigerant. Thus, active cooling is regarded as an environmentally friendly method of cooling. Active cooling using a thermoelectric material can be applied to provide a halocarbon-free refrigerator, a halocarbon-free air conditioner, or a micro-cooling system. In particular, if a thermoelectric element is attached to a memory device, the temperature of the memory device may be maintained at a more uniform and stable level while a volume occupied by the thermoelectric cooler is less than that occupied by an alternative conventional cooling system. Thus, use of a thermoelectric element in a memory device may contribute to higher performance thereof.

Also, when a thermoelectric material is used for thermoelectric power generation based on the Seebeck effect, waste heat may be used as an energy source. Thus, an energy efficiency of a vehicle engine, an exhaust device, a waste incinerator, a steel mill, or a medical device power source which uses heat from the human body, may be increased, or waste heat can be collected for use in another application.

The performance of the thermoelectric material is evaluated using a dimensionless figure-of-merit ZT, which is defined by Equation 1.

$$ZT = \frac{{S}^{2} σ T}{k} \qquad Equation 1$$

In Equation 1, S is the Seebeck coefficient, σ is the electrical conductivity, T is the absolute temperature, and κ is the thermal conductivity.

To increase the dimensionless figure-of-merit ZT, a material having high a Seebeck coefficient, high electrical conductivity, and low thermal conductivity is desirable.

### SUMMARY

Provided is a thermoelectric nano-composite having a high Seebeck coefficient, high electrical conductivity, and low thermal conductivity.

Provided is a thermoelectric module including the thermoelectric nano-composite.

Provided is a thermoelectric apparatus including the thermoelectric modules.

Additional aspects will be set forth in part in the description which follows and, in part, will be apparent from the description.

According to an aspect, disclosed is a thermoelectric nano-composite including: a thermoelectric matrix; a nano-metal particle; and a nano-thermoelectric material represented by Formula 1:

AₓM_{y}B_{z} Formula 1

wherein A includes at least one element of indium, bismuth, or antimony, B includes at least one element of tellurium or selenium, M includes at least one element of gallium, thallium, lead, rubidium, sodium, or lithium, x is greater than 0 and less than or equal to about 4, y is greater than 0 and less than or equal to about 4, and z is greater than 0 and less than or equal to about 3.

According to another aspect, disclosed is a thermoelectric nano-composite including: a thermoelectric matrix; a nano-metal particle formed on a surface of the thermoelectric matrix; and a nano-thermoelectric material disposed at an interface between the thermoelectric matrix and the nano metal particle, wherein the nano-thermoelectric material is represented by Formula 1:

AₓM_{y}B_{z} Formula 1

wherein A includes at least one element of indium, bismuth, or antimony, B includes at least one element of tellurium and selenium, M includes at least one element of gallium, thallium, lead, rubidium, sodium, or lithium, x is greater than 0 and less than or equal to about 4, y is greater than 0 and less than or equal to about 4, and z is greater than 0 and less than or equal to about 3.

Also disclosed is a thermoelectric element including the thermoelectric nano-composite.

Also disclosed is a thermoelectric module including: a first electrode; a second electrode; and the thermoelectric element, wherein the thermoelectric element is disposed between the first electrode and the second electrode.

Also disclosed is a thermoelectric apparatus including: a heat supply source; and a thermoelectric module including: a thermoelectric element which absorbs heat from the heat supply source, and the thermoelectric nano-composite including: a thermoelectric matrix; a nano-metal particle; and a nano-thermoelectric material represented by Formula 1; a first electrode contacting the thermoelectric element; and a second electrode facing the first electrode and contacting the thermoelectric element.

According to another aspect, disclosed is a method of preparing a thermoelectric nano-composite, the method including: contacting a thermoelectric matrix and a nano-sized metal particle to form a combination; and sintering the combination under pressure, wherein the thermoelectric matrix includes at least one element of indium, bismuth, or antimony, and at least one element of tellurium or selenium, and the nano-sized metal particle includes at least one element of gallium, thallium, lead, rubidium, sodium, or lithium.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic diagram illustrating thermoelectric cooling by the Peltier effect;

FIG. 2 is a schematic diagram illustrating thermoelectric power generation by the Seebeck effect;

FIG. 3A is a schematic diagram of an embodiment of a thermoelectric nano-composite, and FIG. 3B is a partial view of the indicated portion of FIG. 3A, wherein the thermoelectric nano-composite is formed by contacting a highly conductive nano-metal particle and a thermoelectric matrix to provide the thermoelectric nano-composite including 3 phases, specifically the thermoelectric matrix, a nano-thermoelectric material, and the nano-metal particle;

FIG. 4 is an embodiment of a thermoelectric module;

FIGS. 5A and 5B are scanning electron microscope (“SEM”) images after heat-treatment of a powder obtained in Example 1;

FIGS. 6A and 6B are SEM images of a fractured bulk material made by sintering the powder obtained in Example 1-2b under pressure;

FIG. 6C is a transmission electron microscope (“TEM”) image of the powder obtained in Example 1-3 after being sintered under pressure, illustrating an embodiment of a nano-metal particle in region A, a nano-thermoelectric material in region B, and a thermoelectric matrix in region C, which are present on a surface of a particle of a thermoelectric nano-composite.

FIG. 6D is a graph of intensity (counts) versus energy (kiloelectron volts, keV) which shows atomic percentages in region A of the powder obtained in Example 1-3 according to energy-dispersive X-ray spectroscopy (“EDX”) analysis;

FIG. 6E is a graph of intensity (counts) versus energy (kiloelectron volts, keV) which shows atomic percentages in region B of the powder obtained in Example 1-3 according to energy-dispersive X-ray spectroscopy (“EDX”) analysis;

FIG. 6F is a graph of intensity (counts) versus energy (kiloelectron volts, keV) which shows atomic percentages in region C of the powder obtained in Example 1-3 according to energy-dispersive X-ray spectroscopy (“EDX”) analysis;

FIG. 7A is a graph of electrical conductivity (Siemens per centimeter, S/cm) versus temperature (Kelvin, K) showing electrical conductivity of a thermoelectric element obtained in Examples 1-1 and 1-3;

FIG. 7B is a graph of Seebeck coefficient (microvolts per Kelvin, μV/K) versus temperature (Kelvin, K) showing a Seebeck coefficient of the thermoelectric element obtained in Examples 1-1 and 1-3;

FIG. 7C is a graph of power factor (watts per square Kelvin-meters, W/K²m) versus temperature (Kelvin, K) showing a power factor of the thermoelectric element obtained in Examples 1-1 and 1-3;

FIG. 7D is a graph of thermal conductivity (watts per Kelvin-meters, W/Km) versus temperature (Kelvin, K) showing thermal conductivity of the thermoelectric element obtained in Examples 1-1 and 1-3;

FIG. 7E is a graph of thermal conductivity (watts per Kelvin-meters, W/Km) versus temperature (Kelvin, K) showing total (filled symbols) and lattice (open symbols) thermal conductivity of the thermoelectric element obtained in Examples 1-1 and 1-3;

FIG. 7F is a graph of figure of merit (ZT) versus temperature (Kelvin, K) showing a thermoelectric figure-of-merit (ZT) of the thermoelectric element obtained in Examples 1-1 and 1-3;

FIGS. 8A and 8B are SEM images after heat-treatment of a powder combined with a cobalt nano-particle obtained in Comparative Example 1-2a;

FIG. 9A is a graph of electrical conductivity (Siemens per centimeter, S/cm) versus temperature (Kelvin, K) showing electrical conductivity of a thermoelectric element obtained in Comparative Example 1-1 and 1-2;

FIG. 9B is a graph of Seebeck coefficient (microvolts per Kelvin, μm/K) versus temperature (Kelvin, K) showing a Seebeck coefficient of the thermoelectric element obtained in Comparative Example 1-1 and 1-2;

FIG. 9C is a graph of thermal conductivity (watts per Kelvin-meters, W/Km) versus temperature (Kelvin, K) showing thermal conductivity of the thermoelectric element obtained in Comparative Example 1-1 and 1-2;

FIG. 9D is a graph of figure of merit (ZT) versus temperature (Kelvin, K) showing a thermoelectric figure-of-merit of the thermoelectric element obtained in Comparative Example 1-1 and 1-2; and

FIG. 9E is a graph of thermal conductivity (watts per Kelvin-meters, W/Km) versus temperature (Kelvin, K) showing total (filled symbols) and lattice thermal conductivity (open symbols) of the thermoelectric element obtained in Comparative Example 1-1 and 1-2.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers and/or sections should not be limited by these terms. These terms are only used to distinguish one element, component, region, layer, or section from another element, component, region, layer or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

A highly efficient thermoelectric nano-composite has a reduced lattice thermal conductivity due to phonon scattering and an increased Seebeck coefficient due to a quantum confinement effect. The thermoelectric nano-composite includes a thermoelectric matrix, a nano-metal particle, and a nano-thermoelectric material represented by Formula 1

AₓM_{y}B_{z} Formula 1

In Formula 1, A includes at least one element of indium (In), bismuth (Bi), or antimony (Sb), B includes at least one element of tellurium (Te) or selenium (Se), M includes at least one element of gallium (Ga), thallium (Tl), lead (Pb), rubidium (Rb), sodium (Na), or lithium (Li), and x is greater than 0 and less than or equal to about 4, y is greater than 0 and less than or equal to about 4, and z is greater than 0 and less than or equal to about 3.

Decreasing the thermal conductivity of a material without decreasing its electrical conductivity may be accomplished by providing electron conductivity while scattering a phonon at an interface of a scattering center according to the Phonon-Glass Electron-Crystal (“PGEC”) effect. The PGEC effect may be realized by introducing a nano-sized material in the thermoelectric matrix to provide a phonon scattering center. The nano-sized material operates as the phonon scattering center to effectively scatter a phonon when the size of the nano-sized material is similar to a length of a mean free path of the phonon in the thermoelectric matrix. Accordingly, the nano-sized material may be used as a phonon scattering center in the thermoelectric matrix. Moreover, the phonon scattering effect improves as the number of interfaces increases.

In order to scatter the phonon while increasing the Seebeck coefficient through a quantum confinement effect, another nano-sized thermoelectric material may be disposed at the interface between the thermoelectric matrix and the nano-metal particle and used as the phonon scattering center.

In an embodiment, the thermoelectric nano-composite has a structure including 3 phases: the thermoelectric matrix 210, a nano-thermoelectric material 220, and the nano-metal particle 200. The structure may be provided by contacting a nano-metal particle that reacts with a thermoelectric matrix at a surface of the thermoelectric matrix, and thus the nano-thermoelectric material, which is a result of the reaction, is formed at an interface between the thermoelectric matrix and the nano-metal particle. The nano-metal particle may be chemically and/or physically bonded to the surface of the thermoelectric matrix, and a portion of the nano-metal particle may be embedded inside the thermoelectric matrix. Examples of the chemical bond include an ionic bond, a metallic bond, or a covalent bond, and examples of the physical bond include adsorption.

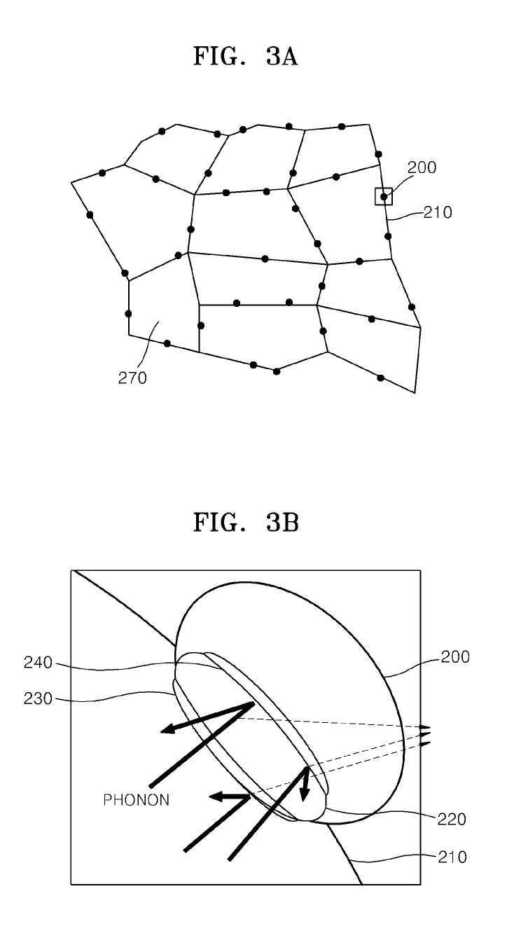

FIGS. 3A and 3B illustrate the structure resulting when the 3 phases are contacted. As shown in FIGS. 3A and 3B, the nano-metal particle 200 reacts with the thermoelectric matrix 210 during a heat-treatment, thereby generating a nano-thermoelectric material 220, which is represented by Formula 1 and which is a thermoelectric material, at the interface of the nano-metal particle 200 and the thermoelectric matrix 210. The size of the nano-thermoelectric material particle generated as a result of the reaction between thermoelectric matrix 210 and the nano-metal particle 200 may be smaller than a size of the nano-metal particle, and thus a Seebeck coefficient may be increased according to a quantum confinement effect due to the phase of the nano-thermoelectric material 220. Also, in addition to the nano-metal particle 200, a first interface (i.e., a first grain boundary 230) between the thermoelectric matrix 210 and the nano-thermoelectric material 220, and a second interface (i.e., a second grain boundary 240) between the nano-thermoelectric material 220 and the nano-metal particle 200 may operate as a phonon scattering center. Accordingly, a thermal conductivity of the material may be decreased more than in the embodiment wherein only the nano-metal particle operates as a phonon scattering center. Also shown in FIG. 3A is grain 270.

The nano-metal particle included in the thermoelectric nano-composite is not limited as long as the nano-metal particle reacts with the thermoelectric matrix to form a nano-thermoelectric material having a composition which is different from the nano-metal particle. For example, the nano-metal particle may be a metal that reacts with the thermoelectric matrix during the sintering under pressure at a temperature of about 350 to about 550° C., specifically about 375 to about 525° C., more specifically about 400 to about 500° C. The metal may form a nano-thermoelectric material having a composition which is different from the nano-metal particle by alloying or otherwise combining with the thermoelectric matrix. For example, the formed thermoelectric material may have a figure-of-merit ZT of about 1.0 or higher. The nano-metal particle may have a melting point of about 550° C. or lower, specifically about 350° C. or lower, more specifically about 100° C. to about 350° C., and may have an electrical conductivity of about 1000 S/cm or higher, specifically about 1000 to about 100,000 S/cm, more specifically about 2000 to about 10,000 S/cm at room temperature. Examples and melting points of a representative embodiment of a nano-metal particle is shown in Table 1, but the nano-metal particle is not limited thereto.

TABLE 1

| Metal | Melting Point (° C.) |
|---|---|
| Ga | 30 |
| Tl | 157 |
| Pb | 327 |
| Rb | 39 |
| Na | 97 |
| Li | 180 |

An average (e.g., average largest) particle diameter of the nano-metal particle may be about 5 to about 50 nanometers (nm), specifically about 10 to about 40 nm, more specifically about 15 to about 35 nm, and the phonon scattering is effective within this range.

The thermoelectric matrix included in the thermoelectric nano-composite is not limited, and may be represented by Formula 2 below.

AₓB_{y} Formula 2

In Formula 2, A includes at least one element of indium (In), bismuth (Bi), or antimony (Sb), B includes at least one element of tellurium (Te) or selenium (Se), x is greater than 0 and less than or equal to about 4, and y is greater than 0 and less than or equal to about 3. In an embodiment, 0<x≦4, and 0<y≦3.

Examples of the thermoelectric matrix include an In—Se thermoelectric material, an In—Te thermoelectric material, or a Bi—Te thermoelectric material. Thus the thermoelectric matrix may comprise In and Se, In and Te, or Bi and Te, for example. Examples of the In—Se thermoelectric material include, but are not limited to, In₄₋ₓGaₓSe_{3±y}, wherein 0≦x≦4 and 0≦y≦1, and In_{4-x-y}GaₓT_{y}Se_{3±z}, or a combination comprising at least one of the foregoing, wherein T denotes a Group 3 to 12 metal, 0≦x≦4, 0≦y≦4, and 0≦z≦1. Herein, “Group” refers to a Group of the Periodic Table of the Elements, according to the International Union of Pure and Applied Sciences Groups 1-18 group classification scheme. Examples of the In—Te thermoelectric material include, but are not limited to, In₄Te_{3±x}, wherein 0≦x≦1. Examples of the Bi—Te thermoelectric material include, but are not limited to, p-type Bi_{0.5}Sb_{1.5}Te₃, or n-type Bi₂Te_{2.7}Se_{0.3}, or a combination comprising at least one of the foregoing.

The thermoelectric matrix and the nano-metal particle may be used in a selected ratio, and for example, the amount of the nano-metal particle may be about 0.05 to about 1 part by weight, specifically about 0.1 to about 0.9 part by weight, more specifically about 0.2 to about 0.8 part by weight, based on 100 parts by weight of the thermoelectric matrix. The phonon scattering may be effective within this range.

The nano-thermoelectric material may be represented by Formula 1, and examples of the nano-thermoelectric material include SbₓPb_{y}Te_{z}, PbₓTe_{y}, BiₓPb_{y}Te_{z}, or (Bi,Sb)ₓPb_{y}Te_{z}, or combination comprising at least one of the foregoing.

AₓM_{y}B_{z} Formula 1

In Formula 1, A includes at least one element of indium (In), bismuth (Bi), or antimony (Sb), B includes at least one element of tellurium (Te) or selenium (Se), M includes at least one element of gallium (Ga), thallium (Tl), lead (Pb), rubidium (Rb), sodium (Na), or lithium (Li), x is greater than 0 and less than or equal to about 4, y is greater than 0 and less than or equal to about 4, and z is greater than 0 and less or equal to about 3. In an embodiment, 0<x≦4, 0<y≦4, and 0<z≦3.

A method of preparing the thermoelectric nano-composite will now be further disclosed.

First, the thermoelectric matrix of Formula 2 may be prepared by using a commercially available thermoelectric material or a thermoelectric material having a selected composition, according to at least any of following methods.

1. An ampoule method, in which starting elements are loaded into an ampoule in a selected ratio, wherein the ampoule may comprise quartz or a metal, then the ampoule is sealed in a vacuum, and then heat-treated.

2. An arc melting method, in which starting elements are loaded in a selected ratio into a chamber and then melted by an arc discharge under an inert gas atmosphere.

3. A solid state reaction method, in which a selected combination of powdered starting materials are sufficiently mixed and sintered under pressure.

4. A metal reflux method, in which a selected ratio of starting elements and an element that provides a condition under which the starting elements can grow into a crystal at high temperature are loaded into a crucible and then heat-treated at high temperature.

5. A Bridgeman method, in which a selected ratio of starting elements are loaded into a crucible and then an end of the crucible is heated at a high-temperature until the starting elements are melted, and then the high temperature region is slowly shifted, thereby locally melting the starting elements until the entirety of the starting elements are exposed to the high-temperature region.

6. An optical floating zone method, in which a selected ratio of starting elements are formed into a seed rod and a feed rod, and then light, which is emitted from a lamp, is focused on a point of the feed rod so that the source elements are locally melted at a high temperature, and then the melted zone is slowly shifted upward.

7. A vapor transport method, in which a selected ratio of starting elements are loaded into a bottom portion of a quartz tube, and then only the bottom portion is heated while a top portion of the quartz tube is maintained at a lower temperature. In the vapor transport method, the source elements are evaporated, a reaction occurs, and the reaction product is condensed at a lower temperature portion of the quartz tube.

8. A mechanical alloying method, in which a powder of the starting material and a steel ball are loaded into a cemented carbide vessel and then the cemented carbide vessel is rotated, thereby forming an alloy-type thermoelectric material by mechanical impact of the steel ball on the starting material.

A combination of the thermoelectric matrix and the nano-metal particle may be formed by combining a thermoelectric matrix powder and a metal precursor, such as a metal acetate. Alternatively, the combination may be formed by dissolving or suspending a metal precursor, such as a metal acetate or a metal nitrate, in an organic solvent, such as ethanol, acetone, ethyl acetate, or oleic acid, and then spraying the dissolved metal precursor (or suspension) to provide the thermoelectric matrix powder, or by dissolving the thermoelectric matrix powder and the metal precursor together in the organic solvent, and then performing a solvothermal method using microwaves on the organic solvent.

When the solvothermal method using microwaves is used, the metal precursor may be uniformly distributed at an interface of the thermoelectric matrix powder. Also, a particle of a metal having a uniform nano-size, and the organic solvent, such as an oleic acid, which operates as a surfactant, may be combined to provide a nuclei of the metal which is further grown.

The metal may include at least one element of gallium (Ga), thallium (Tl), lead (Pb), rubidium (Rb), sodium (Na), or lithium (Li) as is further disclosed above, and the metal may be contained in a selected weight ratio. The weight ratio of the metal precursor including the metal may be from about 0.05 to about 1 part by weight, specifically about 0.1 to about 0.9 part by weight, more specifically about 0.2 to about 0.8 part by weight, based on 100 parts by weight of the thermoelectric matrix.

The metal precursor may be, for example, a metal acetate that does not aggregate in a chalcogenide thermoelectric matrix, and increases dispersibility of nano-particles. While not wanting to be bound by theory, it is believed that the metal of the metal precursor chemically bonds with the chalcogenide thermoelectric matrix because a surface charge of the chalcogenide thermoelectric matrix is negative and a surface charge of the metal is positive. Also, a metal-acetate compound of various metals is easily obtained.

A thermoelectric nano-composite may be prepared by sintering the combination of the thermoelectric matrix and the metal precursor under pressure. By using a sintering temperature which is higher than the melting point of the metal, the metal particle may be liquid at an interface of the thermoelectric matrix during a heat-treatment. Accordingly, the metal may easily react with the thermoelectric matrix. By selecting the heat-treatment conditions, such as a sintering temperature and a sintering time, the three phases of the thermoelectric nano-composite: a thermoelectric matrix, a nano-thermoelectric material which is formed when a nano-metal particle and the thermoelectric matrix react with each other, and the nano metal particle, may be formed.

The combination may be sintered under a pressure of about 30 to about 1000 megaPascals (MPa), specifically about 40 to about 500 MPa, more specifically about 50 to about 100 MPa, at a temperature of about 300 to about 550° C., specifically about 325 to about 500° C., more specifically about 350 to about 450° C., for a time of about 1 minute to about 1 hour, specifically about 2 minutes to about 30 minutes, more specifically from about 5 minutes to about 10 minutes.

A thermoelectric element may be obtained by molding a thermoelectric material, for example, by cutting. When the thermoelectric material has a single crystal structure, a cutting direction of the thermoelectric material may be perpendicular to a crystal growth direction.

The thermoelectric element may be a p-type thermoelectric element or an n-type thermoelectric element. The thermoelectric element may be comprise a thermoelectric material in a selected shape, for example, a rectangular parallelepiped shape.

Also, the thermoelectric element may be an element that is connected to an electrode and generates a cooling effect when a current is applied thereto, or an element for generating power due to a difference in temperature.

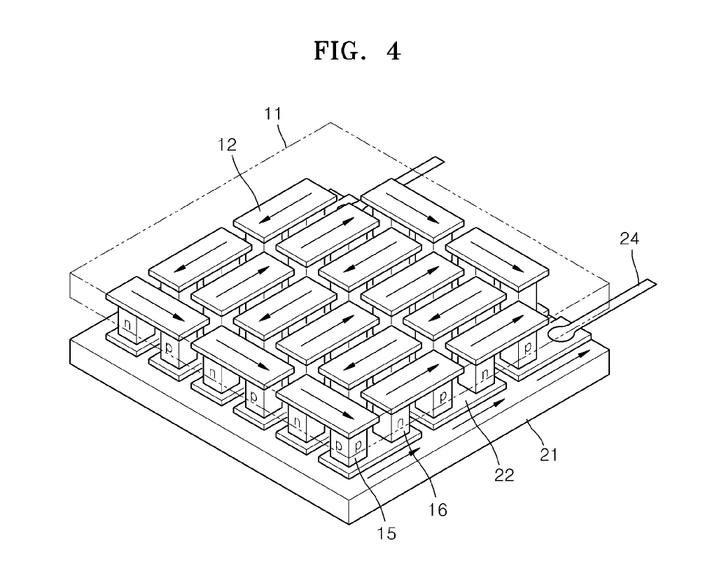

FIG. 4 illustrates an embodiment of a thermoelectric module including the thermoelectric element. Referring to FIG. 4, a top electrode 12 and a bottom electrode 22 are patterned on a top insulating substrate 11 and a bottom insulating substrate 21, respectively, and the top electrode 12 and the bottom electrode 22 contact a p-type thermoelectric component 15 and an n-type thermoelectric component 16. The top electrode 12 and the bottom electrode 22 are connected to the outside of the thermoelectric element by a lead electrode 24.

The top and bottom insulating substrates 11 and 21, respectively, may comprise gallium arsenide (GaAs), sapphire, silicon, FIREX, or quartz, or a combination comprising at least one of the foregoing. The top and bottom electrodes 12 and 22 may each independently include aluminum, nickel, gold, or titanium, or a combination comprising at least one of the foregoing, and may have various sizes. The top and bottom electrodes 12 and 22 may each independently be formed using various known patterning methods, such as a lift-off semiconductor process, a deposition method, or a photolithography method.

A thermoelectric module according to another embodiment may include a first electrode, a second electrode, and a thermoelectric matrix represented by Formula 1 disposed between the first and second electrodes. Such a thermoelectric module may further include an insulating substrate on which at least one of the first electrode and the second electrode is disposed, like the thermoelectric module of FIG. 4. The insulating substrate may be identical to any one of the top and bottom insulating substrates 11 and 21.

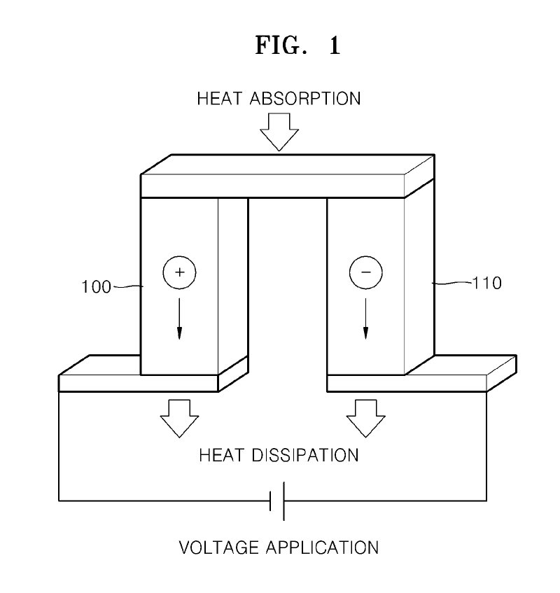

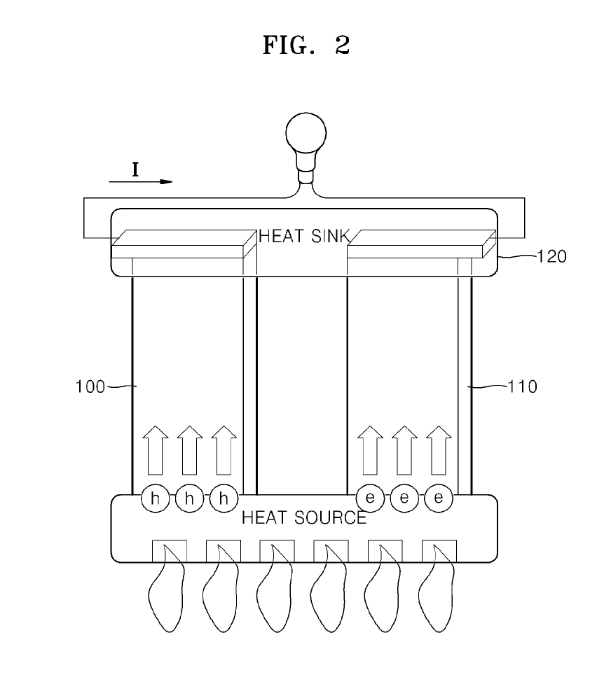

According to an embodiment, any one of the first electrode and the second electrode may be exposed to the heat source as shown in FIG. 2. According to another embodiment, any one of the first electrode and the second electrode may be electrically connected to a power supply source as shown in FIG. 1, or to a device outside the thermoelectric module, for example, to an electrical device, such as a battery cell that consumes or stores power.

According to another embodiment, any one of the first electrode and the second electrode may be electrically connected to a power supply source as shown in FIG. 1.

According to an embodiment, the p-type thermoelectric component 15 and the n-type thermoelectric component 16 may be alternately disposed as shown in FIG. 4, and at least one of the p-type thermoelectric component 15 and the n-type thermoelectric component 16 may include the nano-thermoelectric material of Formula 1 above.

A thermoelectric apparatus according to an embodiment includes a heat supply source and a thermoelectric module, wherein the thermoelectric module absorbs heat from the heat supply source, and includes the nano-thermoelectric material represented by Formula 1 above, a first electrode, and a second electrode, wherein the first and second electrodes face each other. One of the first and second electrodes may contact the nano-thermoelectric material.

The thermoelectric apparatus may further include a power supply source which is electrically connected to the first and second electrodes. The thermoelectric apparatus may further include an electrical device which is electrically connected to one of the first and second electrodes.

The thermoelectric nano-composite, the thermoelectric element, the thermoelectric module, and the thermoelectric apparatus may be used in, for example, a thermoelectric cooling system or a thermoelectric power generation system. The thermoelectric cooling system may be a micro-cooling system, a cooling device, an air conditioner, or a waste heat power generation system, but is not limited thereto. The other components and manufacturing method of the thermoelectric cooling system or thermoelectric apparatus may be determined by one of skill in the art without undue experimentation, and thus will not be described in further detail herein.

Hereinafter, an embodiment is disclosed in further detail with reference to the following examples. However, these examples shall not limit the scope of the present disclosure.

### Example 1-1

Bi_{0.5}Sb_{1.5}Te₃ powder, which is a p-type thermoelectric matrix material, was synthesized using an attrition mill of the type that is used for mechanical alloying. In further detail, bismuth (Bi), antimony (Sb), and tellurium (Te), which are starting elements, and steel balls having a diameter of 5 millimeters (mm) were loaded into a cemented carbide jar and N₂ gas was provided thereto to prevent oxidation of the starting elements. In this regard, the weight of the steel balls was 20 times greater than the total weight of all the starting elements. An impeller formed of cemented carbide was rotated in the cemented carbide jar at a speed of 500 revolutions per minute (rpm), and the oxidation of the starting elements caused by heat generated during rotation was prevented by providing cooling water to the outside of the cemented carbide jar.

### Example 1-2

Pb-acetate (lead(II)-acetate: Pb(CH₃COO)₂) was dry-mixed with the Bi_{0.5}Sb_{1.5}Te₃ powder prepared as above by using a ball mill, wherein the amounts of Pb contained in Pb-acetate were 0.3 (Example 1-2a), 0.5 (Example 1-2b), and 0.7 (Example 1-2c) part by weight based on 100 parts by weight of the Bi_{0.5}Sb_{1.5}Te₃ powder.

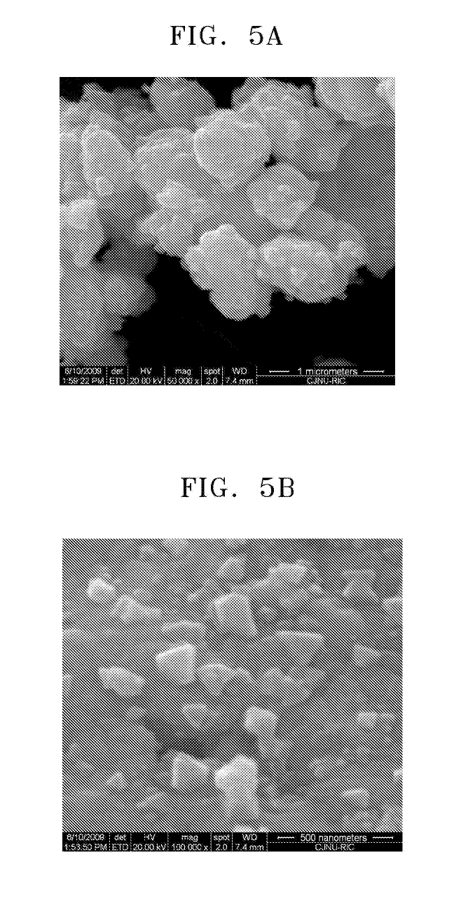

In order to remove acetate, the mixed powder of the Bi_{0.5}Sb_{1.5}Te₃ powder and the Pb-acetate was heat-treated for 3 hours at a temperature of 300° C. under an inert atmosphere of N₂. FIGS. 5A and 5B are scanning electron microscope (SEM) images at 50,000 and 100,000 times magnification, respectively illustrating a minute structure of the mixed powder of Example 1-2b after the Pb-acetate is mixed with the Bi_{0.5}Sb_{1.5}Te₃ powder and then heat-treated, wherein the amount of Pb contained in Pb-acetate was 0.5 part by weight based on 100 parts by weight of the Bi_{0.5}Sb_{1.5}Te₃ powder. As shown in FIGS. 5A and 5B, a power having a nano-granule shape is formed wherein Pb particles having a size on the scale of tens of nanometers are distributed and combined with the surface of the Bi_{0.5}Sb_{1.5}Te₃ powder, which has a size on the scale of several micrometers.

### Example 1-3

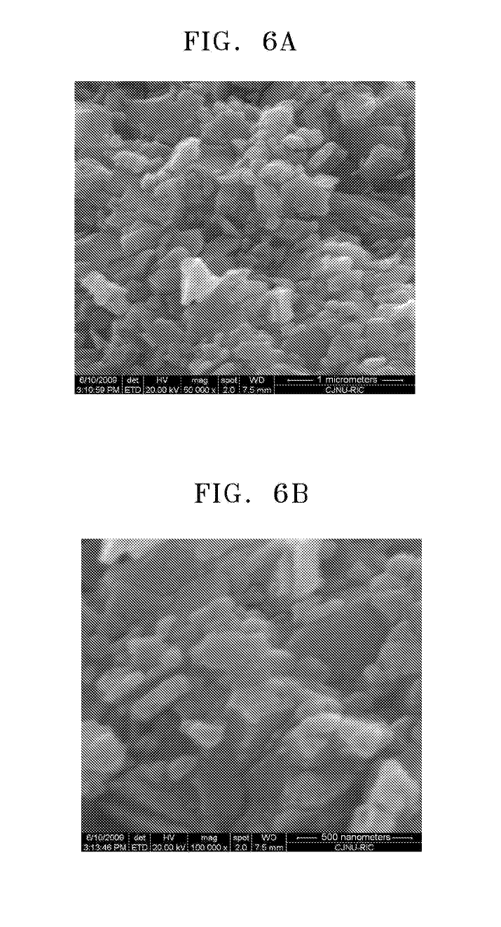

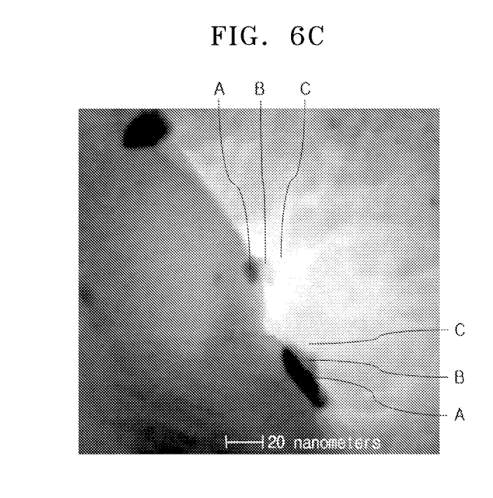

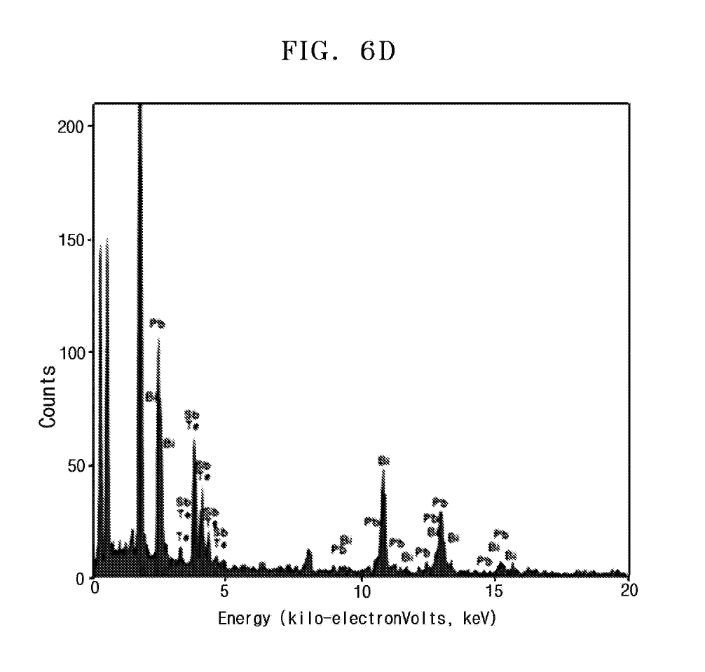

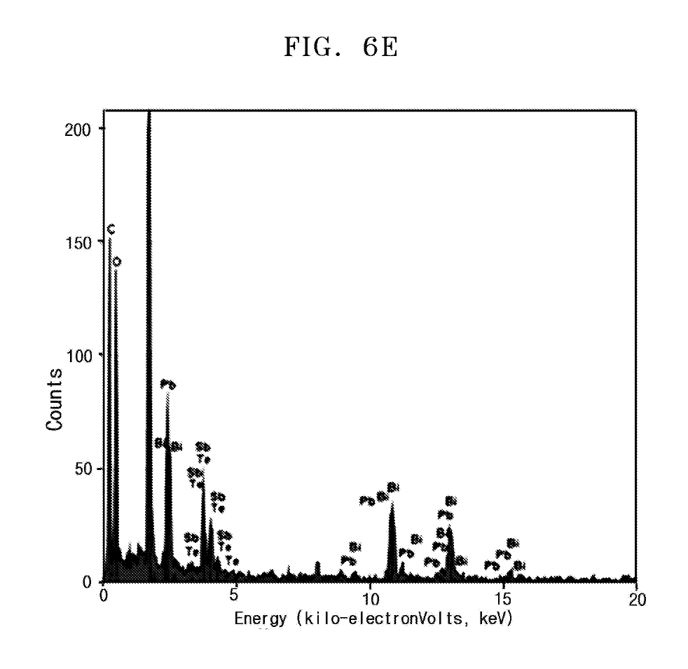

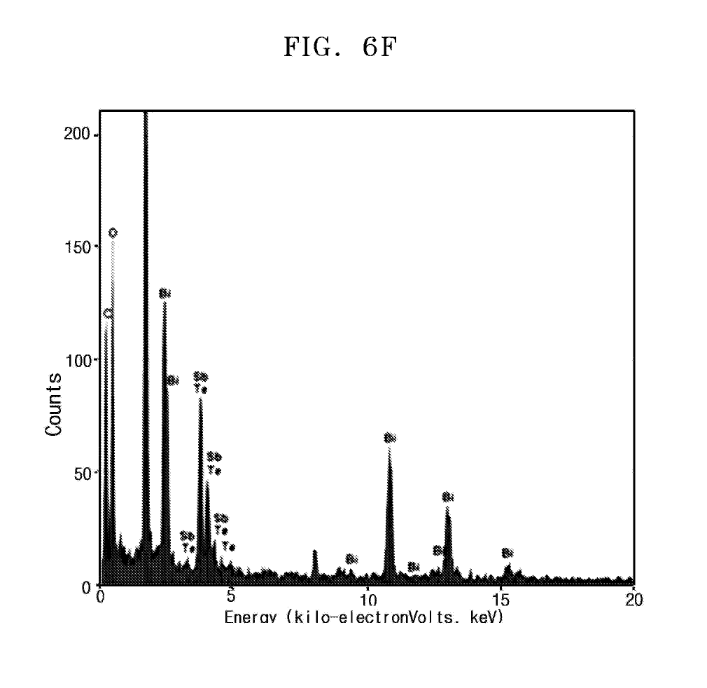

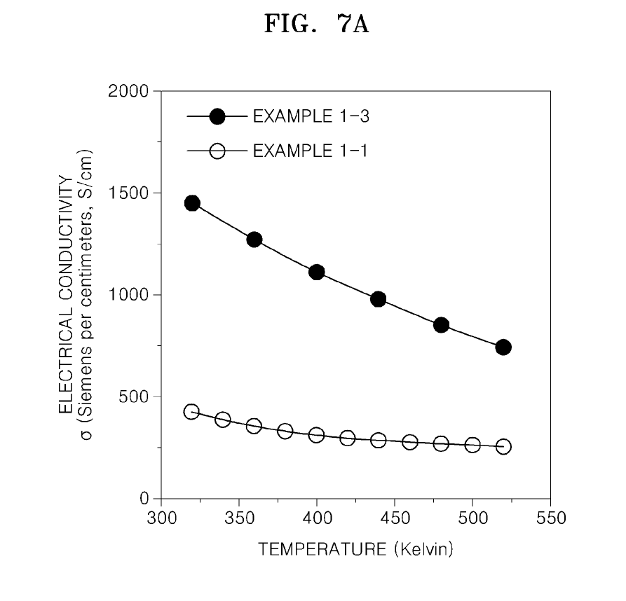

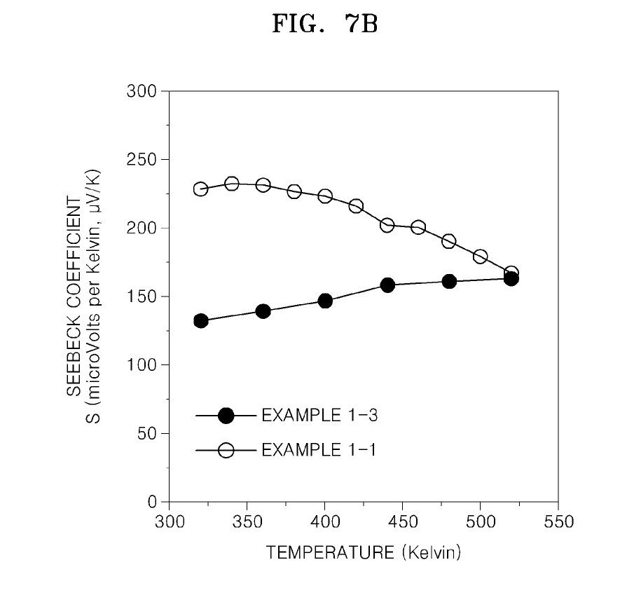

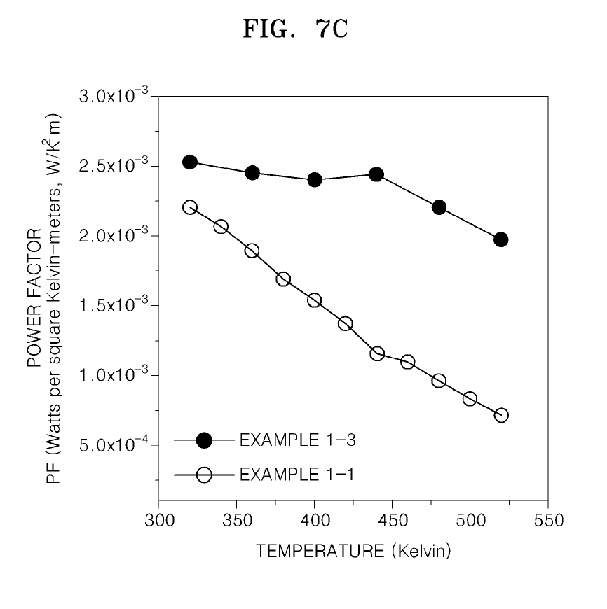

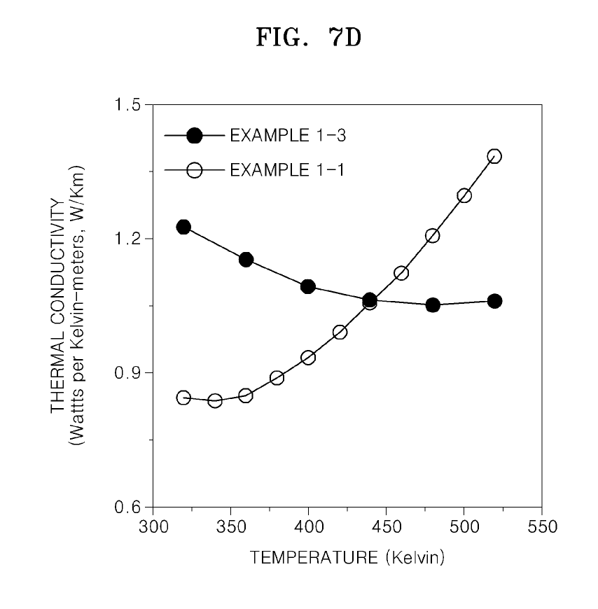

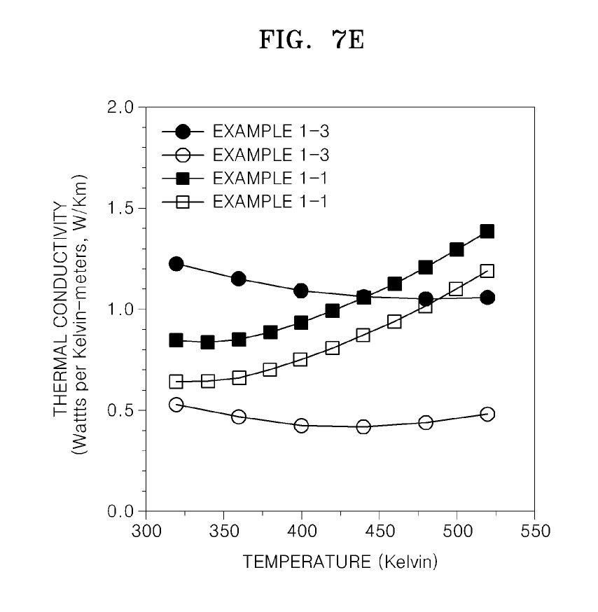

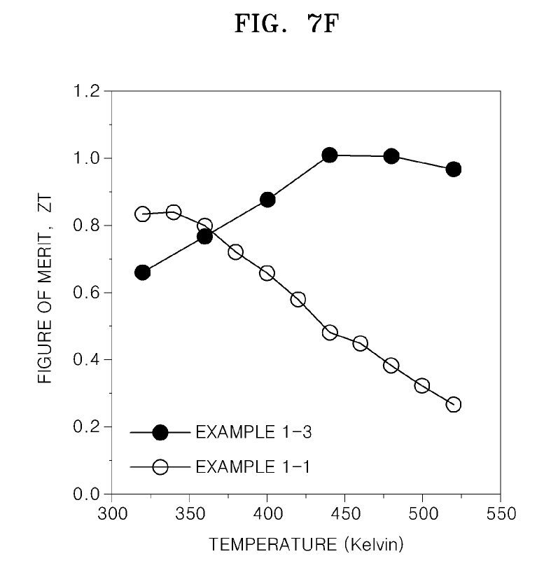

The powder of each of Examples 1-2b having the nano-granule shape was loaded into a graphite mold and then hot pressed at a temperature of 380° C., at a pressure of 70 megaPascals (MPa), and under a vacuum of 10⁻² torr or less, to prepare a thermoelectric nano-composite, respectively. FIGS. 6A and 6B are SEM images at 50,000 and 100,000 times magnification, respectively, illustrating the thermoelectric nano-composite of Example 1-3, which was prepared using the material of Example 1-2b, which contained 0.5 part by weight of Pb contained in Pb-acetate. Thermoelectric characteristics, such as electrical conductivity, Seebeck coefficient, power factor, and thermal conductivity of the thermoelectric nano-composite are shown in FIGS. 7A through 7F. As shown in FIGS. 6A and 6B, Pb nano-particles are uniformly distributed on the Bi_{0.5}Sb_{1.5}Te₃ powder.

FIG. 6C is a transmission electron microscope (“TEM”) image of the thermoelectric nano-composite of Example 1-3, which was prepared using the material of Example 1-2b which contained 0.5 part by weight of Pb contained in Pb-acetate. Referring to FIG. 6C, shown are the three phases, including a nano-metal particle in region A, a nano-thermoelectric material in region B, and a thermoelectric matrix in region C, wherein the nano-thermoelectric material is at an interface between the nano-metal particle and the thermoelectric matrix. A TEM-energy-dispersive X-ray spectroscopy (“EDX”) analysis of the A, B, and C regions of the thermoelectric nano-composite prepared by using the material of Example 1-3b, which contained 0.5 part by weight of Pb contained in Pb-acetate, is shown in FIGS. 6D to 6F, respectively. Comparing an amount of the nano-metal particle in the A, B, and C regions of FIG. 6C, an atomic percentage of the nano-metal particle is the highest in the A region, the atomic percentage of the nano-metal particle is lower in the B region than in the A region, and the nano-metal particle is not detected in the C region. The composition of the thermoelectric matrix in the A region is detected because a penetration depth of an EDX beam is several micrometers. Accordingly, when the EDX beam is focused on the nano-metal particle having a size of tens of nanometers, the composition of the thermoelectric matrix under the nano-metal particle is also measured. After a sintering process under pressure, the nano-metal particles on the surface of the thermoelectric matrix partially react with the thermoelectric matrix, and thus the nano-thermoelectric material is formed.

As shown in FIG. 7A, electrical conductivity of the thermoelectric nano-composite having the 3 phase structure of the nano-metal particle, the nano-thermoelectric material, and the thermoelectric matrix is higher than that of the Bi_{0.5}Sb_{1.5}Te₃ (“SBT”) of Example 1-1. As the electrical conductivity increases, a Seebeck coefficient decreases as shown in FIG. 7B. Although a power factor of the thermoelectric nano-composite and the Bi_{0.5}Sb_{1.5}Te₃ are not different at 320 K, as the temperature increases, the power factor of the thermoelectric nano-composite is 2.5 times higher than the power factor of the Bi_{0.5}Sb_{1.5}Te₃ at 520 K, as shown in FIG. 7C.

Also, as shown in FIG. 7D, the thermal conductivity of the thermoelectric nano-composite is high compared to that of the Bi_{0.5}Sb_{1.5}Te₃ at a temperature range of 320 K to 440K. While not wanting to be bound by theory, it is believed that the high thermal conductivity may be because the electron contribution to the thermal conductivity increased according to the increase of the electrical conductivity, as shown in Equation 2 below.

κ=e+L Equation 2

In Equation 2, κ is the thermal conductivity, e is the electron contribution to the thermal conductivity, from electron or hole conductivity, for example, and L is the lattice contribution to the thermal conductivity, from the thermal conductivity of the lattice due to phonon conduction, for example.

In order to check the decrease of the thermal conductivity in the thermoelectric nano-composite according to a PGEC behavior, FIG. 7E illustrates total thermal conductivity (filled symbols) and the lattice contribution to the thermal conductivity (open symbols). Referring to FIG. 7E, PGEC behavior is present because the lattice thermal conductivity of the thermoelectric nano-composite decreases compared to that of the Bi_{0.5}Sb_{1.5}Te₃ in the temperature range of 320 K to 520 K, and in particular, the PGEC effect increases as the temperature increases, and thus the lattice thermal conductivity of the thermoelectric nano-composite is at least 50% lower than that of the Bi_{0.5}Sb_{1.5}Te₃ at the temperature of 520 K.

Also is as shown in FIG. 7F, a thermoelectric figure-of-merit ZT of the thermoelectric nano-composite increases, unlike the Bi_{0.5}Sb_{1.5}Te₃, which has a thermoelectric figure-of-merit ZT that remarkably decreases as the temperature is increased. Accordingly, the thermoelectric performance index ZT of the thermoelectric nano-composite is about 2.5 times higher than that of the Bi_{0.5}Sb₁ Te₃ at 520 K.

### Example 2-1

Bi_{0.5}Sb_{1.5}Te₃ powder, which is a p-type thermoelectric matrix material, was synthesized using an attrition mill of the type that is used for mechanical alloying. In detail, bismuth (Bi), antimony (Sb), and tellurium (Te), which are starting elements, and steel balls having a diameter of 5 mm were loaded into a cemented carbide jar and N₂ gas was provided thereto to prevent oxidation of the starting elements. In this regard, the weight of the steel balls was 20 times greater than the total weight of all the starting elements. An impeller formed of cemented carbide was rotated in the cemented carbide jar at a speed of 500 rpm, and the oxidation of the starting elements caused by heat generated while rotating was prevented by providing cooling water to the outside of the cemented carbide jar.

### Example 2-2

Pb-acetate (Lead(II) acetate: Pb(CH₃COO)₂) having 0.5 part by weight of Pb based on 100 parts by weight of the Bi_{0.5}Sb_{1.5}Te₃ powder was mixed with 50 milliliters (mL) of ethanol, and then dissolved therein for 1 hour using a stirrer. Then, the Pb-acetate was uniformly sprayed on the Bi_{0.5}Sb_{1.5}Te₃ powder. Next, the Bi_{0.5}Sb_{1.5}Te₃ powder was mixed using a mortar until a dried powder was obtained when the ethanol evaporated.

A mixed powder of the Bi_{0.5}Sb_{1.5}Te₃ powder and the Pb-acetate was heat-treated under an inert atmosphere of N₂, to prepare a nano-granule in which a nano-metal particle is combined with a thermoelectric matrix. The nano-granule was loaded into a graphite mold and hot-pressed at a temperature of 380° C., at pressure of 70 MPa, and under vacuum of 10⁻² torr or less, so as to prepare a thermoelectric nano-composite.

### Example 3-1

Bi_{0.5}Sb_{1.5}Te₃ powder, which is a p-type thermoelectric matrix material, was synthesized using an attrition mill of the type that is used for mechanical alloying. In further detail, bismuth (Bi), antimony (Sb), and tellurium (Te), which are starting elements, and steel balls having a diameter of 5 mm were loaded into a cemented carbide jar and N₂ gas was provided thereto to prevent oxidation of the starting elements. In this regard, the weight of the steel balls was 20 times greater than the total weight of all the starting elements. An impeller formed of cemented carbide was rotated in the cemented carbide jar at a speed of 500 rpm, and the oxidation of the starting elements caused by heat generated during rotation was prevented by providing cooling water to the outside of the cemented carbide jar.

### Example 3-2

A 2 gram (g) quantity of Bi_{0.5}Sb_{1.5}Te₃ powder was mixed with 25 mL of phenyl ether, in which 0.0102 g of lead(II) acetate trihydrate having 0.5 part by weight of Pb based on 100 parts by weight of the Bi_{0.5}Sb_{1.5}Te₃ powder and 5 mL of oleic acid are mixed. The mixture thereof was loaded into an autoclave, and then stirred and irradiated with microwave radiation for 20 minutes at a temperature of 150° C., to dissolve the lead(II) acetate trihydrate in the phenyl ether. Next, the microwave radiation was irradiated for 5 minutes at a temperature of 220° C. so that the dissolved lead(II) acetate trihydrate formed a nucleus and grew on the surface of the Bi_{0.5}Sb_{1.5}Te₃ powder. The Bi_{0.5}Sb_{1.5}Te₃ powder combined with the Pb nano-particle mixed in the phenyl ether and the oleic acid was collected using a centrifugal separator. In order to clean the phenyl ether and the oleic acid left on the surface of the Bi_{0.5}Sb_{1.5}Te₃ powder combined with the Pb nano-particle, the Bi_{0.5}Sb_{1.5}Te₃ powder was repeatedly cleaned 2 to 3 times using hexane and collected using the centrifugal separator, and then cleaned using ethanol and collected using the centrifugal separator.

The separated Bi_{0.5}Sb_{1.5}Te₃ powder combined with the Pb nano-particle was dried in a convection oven for 24 hours at a temperature of 70° C. The dried powder thereof was heat-treated for 3 hours at a temperature of 300° C. while provided with nitrogen gas, to obtain a nano-granule, in which a nano-metal particle is combined with the Bi_{0.5}Sb_{1.5}Te₃ powder.

The nano-granule was loaded into a graphite mold and hot-pressed under a vacuum of 10⁻² torr or less, at pressure of 70 MPa, and at a temperature of 380° C., thereby preparing a thermoelectric element.

### Comparative Example 1

Metals such as cobalt (Co), tin (Sn), and zinc (Zn) are used as comparative examples, wherein Co and Zn are understood to hardly react with a Bi—Te matrix because their melting points are higher than the heat-treatment temperature, and Sn does not synthesize a nano-thermoelectric material having another phase by reacting with a Bi—Te matrix due to its high resistance.

Co-Acetate (Cobalt(II) Acetate: Co(CH₃COO)₂) (Co Melting Point: 1495° C.)

Sn-Acetate (Tin(II) Acetate: Sn(CH₃COO)₂) (Sn Melting Point: 231° C.)

Zn-Acetate (Zinc(II) Acetate: Zn(CH₃COO)₂) (Zn Melting Point: 419° C.)

### Comparative Example 1-1

Bi_{0.5}Sb_{1.5}Te₃ powder, which is a p-type thermoelectric matrix material, was synthesized using an attrition mill of the type that is used for mechanical alloying. In further detail, bismuth (Bi), antimony (Sb), and tellurium (Te), which are starting elements, and steel balls having a diameter of 5 mm were loaded into a cemented carbide jar and N₂ gas was provided thereto to prevent oxidation of the starting elements. In this regard, the weight of the steel balls was 20 times greater than the total weight of all the starting elements. An impeller formed of cemented carbide was rotated in the cemented carbide jar at a speed of 500 rpm, and the oxidation of the starting elements caused by heat generated during rotation was prevented by providing a cooling water to the outside of the cemented carbide jar.

### Comparative Example 1-2

Co-acetate (Cobalt(II) acetate: Co(CH₃COO)₂) (Comparative Example 1-2a, “CEx 1-2a”), Sn-acetate (Tin(II) acetate: Sn(CH₃COO)₂) (Comparative Example 1-2b, “CEx 1-2b”), and Zn-acetate (Zinc(II) acetate: Zn(CH₃COO)₂) (Comparative Example 1-2c, “CEx 1-2c”) were each dry-mixed with the Bi_{0.5}Sb_{1.5}Te₃ powder of Comparative Example 1-1 using a mortar, in which the amounts of Co, Sn, or Zn respectively contained in the Co-acetate, the Sn-acetate, or the Zn-acetate mixture were each 0.15 part by weight based on 100 parts by weight of the Bi_{0.5}Sb_{1.5}Te₃ powder.

The mixture of the Bi_{0.5}Sb_{1.5}Te₃ powder, and the Co-acetate, the Sn-acetate, or the Zn-acetate were heat-treated under an inert atmosphere of N₂ gas, thereby preparing a powder having a nano-granule shape, in which a nano-metal particle is combined with the Bi_{0.5}Sb_{1.5}Te₃ powder. During the heat-treatment, an organic component volatilizes, and the nano-metal particle is combined with the Bi_{0.5}Sb_{1.5}Te₃ powder.

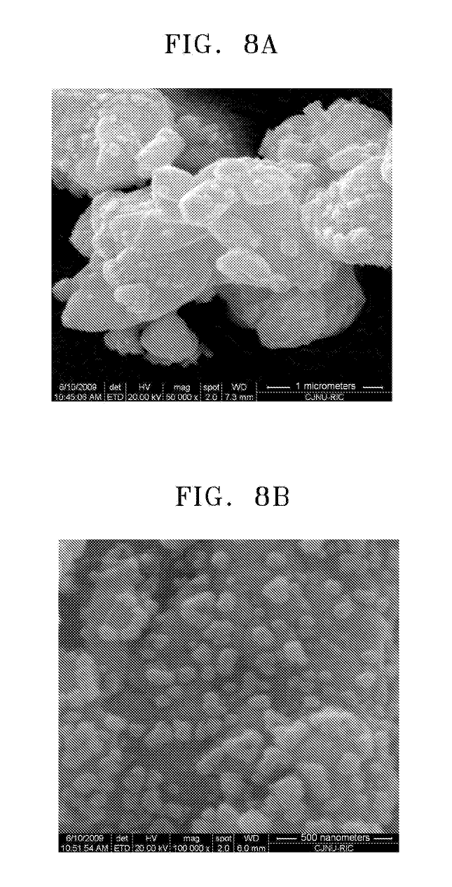

FIGS. 8A and 8B are SEM images of powder after the heat-treatment at 50,000 and 100,000 times magnification, respectively, when the Co-acetate is used. Referring to FIGS. 8A and 8B, the powder having a nano-granule shape having a size of several micrometers, in which a Co particle having a size on the scale of tens of nanometers, is distributed and combined on the surface of the Bi_{0.5}Sb_{1.5}Te₃ powder, is formed.

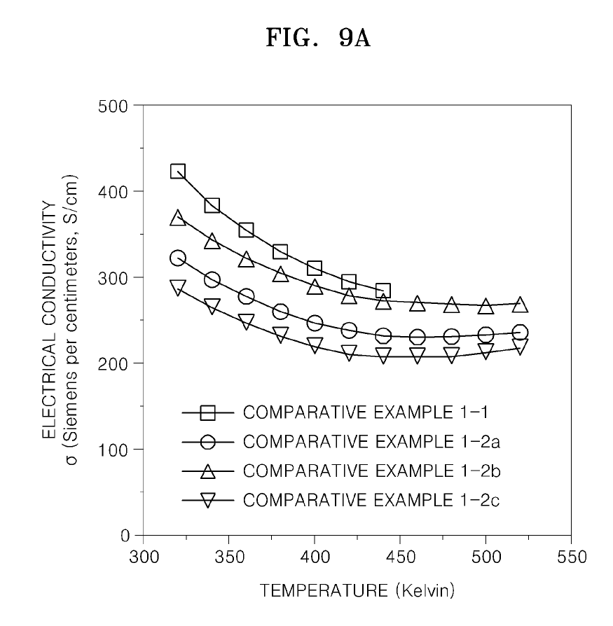

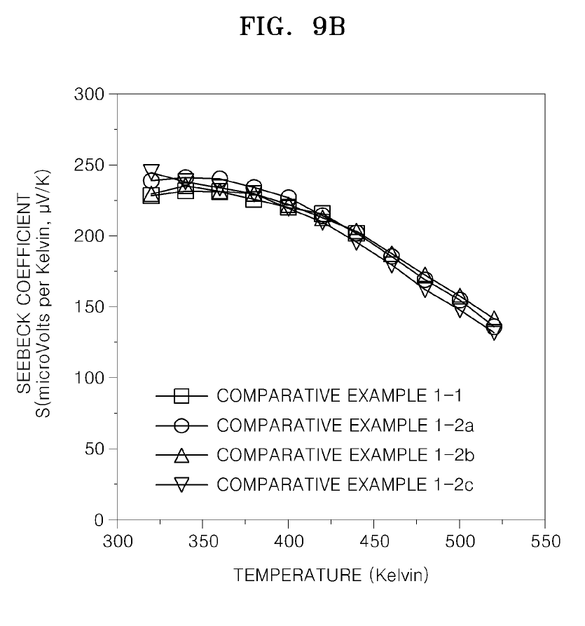

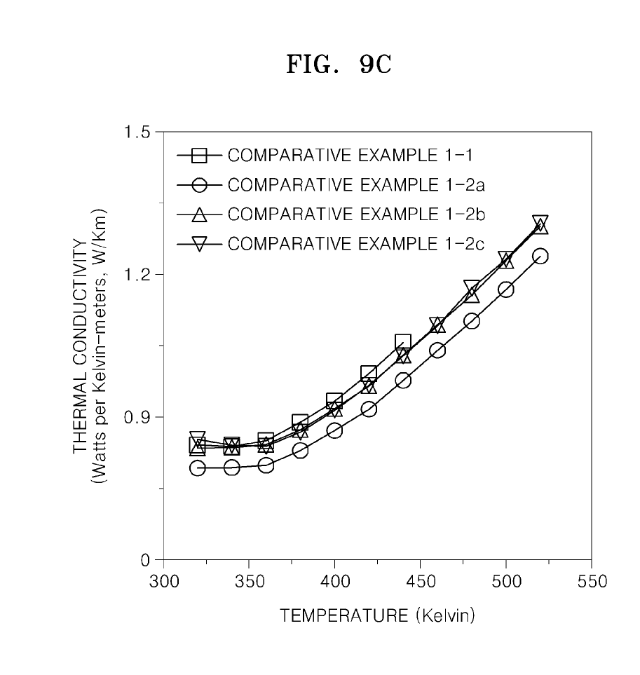

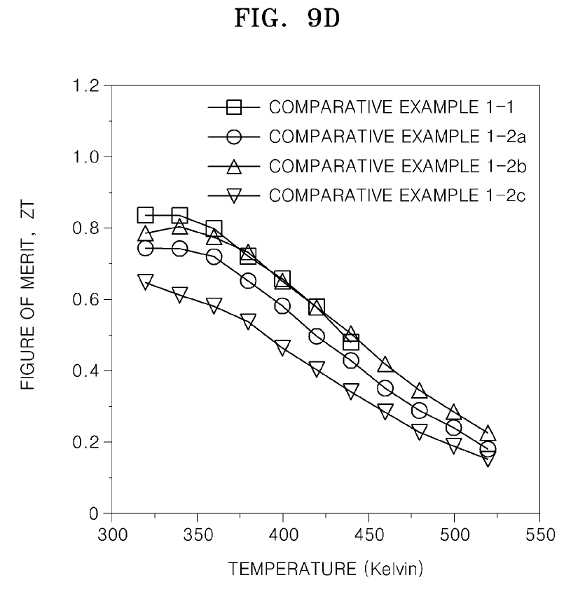

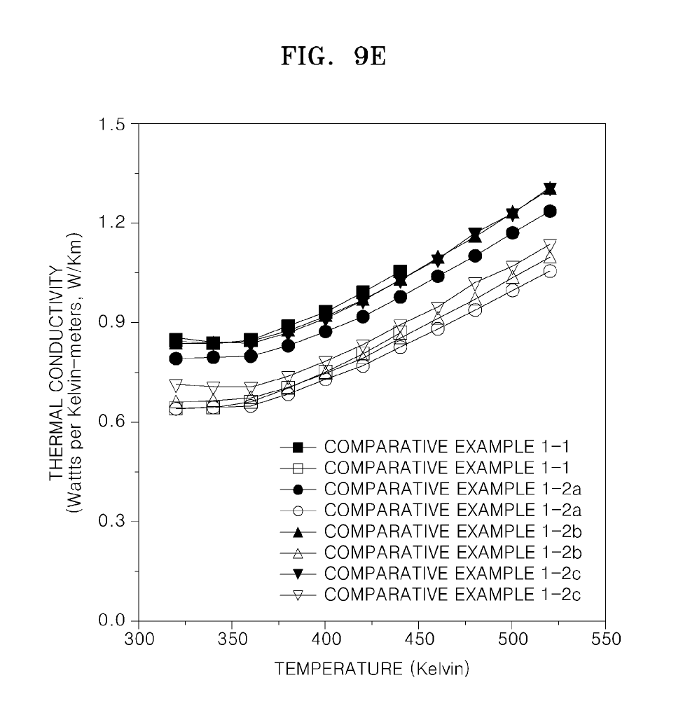

The powder having a nano-granule shape was loaded into a graphite mold and hot-pressed under a vacuum of 10⁻² torr or less, at a pressure of 70 MPa, and at a temperature of 380° C. to prepare a thermoelectric element. Thermoelectric characteristics, such as electrical conductivity, Seebeck coefficient, power factor, and thermal conductivity of the thermoelectric element were evaluated, and the results are shown in FIGS. 9A through 9E.

As shown in FIG. 9A, the electrical conductivity of the thermoelectric elements including Co, Sn, or Zn are lower than that of the Bi_{0.5}Sb_{1.5}Te₃. As shown in FIG. 9B, as the electrical conductivity decreases, the Seebeck coefficient increases by a small amount, and thus the thermoelectric elements including Co, Sn, or Zn a Seebeck coefficient which is similar to that of the Bi_{0.5}Sb_{1.5}Te₃. However, the power factors of the thermoelectric elements including Co, Sn, or Zn are lower than the power factor of Bi_{0.5}Sb_{1.5}Te₃. A power factor is obtained by multiplying a value of electric conductivity by a square of a Seebeck coefficient. Also, as shown in FIG. 9C, the thermal conductivity of the thermoelectric elements including Co, Sn, or Zn are similar or lower than the thermal conductivity of Bi_{0.5}Sb_{1.5}Te₃. While not wanting to be bound by theory, it is believed that this is because an electron contribution to the thermal conductivity decreased according to the decrease in the electrical conductivity.

In order to check the decrease of the thermal conductivity in the thermoelectric elements of Comparative Example 1 for PGEC behavior, FIG. 9E illustrates the total thermal conductivity (filled symbols) and the lattice contribution of the thermal conductivity (open symbols). The decrement of the lattice thermal conductivity of the thermoelectric elements of Comparative Example 1 is insignificant compared to Bi_{0.5}Sb_{1.5}Te₃ in the temperature range of 320 K to 520 K. As a result, as shown in FIG. 9D, thermoelectric figure-of-merit ZT of the thermoelectric elements of Comparative Example 1 are lower than a thermoelectric figure-of-merit ZT of Bi_{0.5}Sb_{1.5}Te₃.

As disclosed above, according to an embodiment, a thermoelectric nano-composite has a high Seebeck coefficient, high electrical conductivity, and very low thermal conductivity, and thus has an excellent figure-of-merit ZT. A thermoelectric module and a thermoelectric apparatus including the thermoelectric nano-composite may be useful for a cooling device, such as halocarbon-free refrigerator or air conditioner, a waste heat power generation system, a thermoelectric nuclear power generator for military and aerospace purposes, or a micro-cooling system.

It should be understood that the embodiments disclosed herein shall be considered in a descriptive sense only and not for purposes of limitation. Descriptions of features, advantages, or aspects of each embodiment shall be considered as available for other similar features, advantages, or aspects in other embodiments.

What is claimed is:

1. A thermoelectric nano-composite comprising:
a thermoelectric matrix;
a nano-metal particle; and
a nano-thermoelectric material represented by Formula 1:
AₓM_{y}B_{z} Formula 1
wherein
A comprises at least one element of indium, bismuth, or antimony,
B comprises at least one element of tellurium or selenium,
M comprises at least one element of gallium, thallium, lead, rubidium, sodium, or lithium,
x is greater than 0 and less than or equal to about 4,
y is greater than 0 and less than or equal to about 4, and
z is greater than 0 and less than or equal to about 3.

2. The thermoelectric nano-composite of claim 1, wherein the nano-metal particle is disposed on a surface of the thermoelectric matrix.

3. The thermoelectric nano-composite of claim 1, wherein the nano-thermoelectric material is disposed at an interface between the thermoelectric matrix and the nano-metal particle.

4. The thermoelectric nano-composite of claim 1, wherein the thermoelectric matrix is a Bi—Te thermoelectric material, an In—Te thermoelectric material, or an In—Se thermoelectric material, or a combination comprising at least one of the foregoing.

5. The thermoelectric nano-composite of claim 1, wherein the thermoelectric matrix is represented by Formula 2:
A₂B₃ Formula 2
wherein A comprises at least one element of indium, bismuth, or antimony, and B comprises at least one element of tellurium, or selenium.

6. The thermoelectric nano-composite of claim 1, wherein a particle size of the nano-thermoelectric material is smaller than a particle size of the nano-metal particle.

7. The thermoelectric nano-composite of claim 1, further comprising
a first interface between the thermoelectric matrix and the nano-thermoelectric material, and
a second interface between the nano-thermoelectric material and the nano-metal particle,
wherein the first and second interfaces are each a phonon scattering center.

8. The thermoelectric nano-composite of claim 1, wherein the melting point of the nano-metal particle is about 350° C. or less.

9. The thermoelectric nano-composite of claim 1, wherein the nano-metal particle comprises at least one element of gallium, thallium, lead, rubidium, sodium, or lithium.

10. The thermoelectric nano-composite of claim 1, wherein the thermoelectric matrix is a bulk material.

11. A thermoelectric nano-composite comprising:
a thermoelectric matrix;
a nano-metal particle disposed on a surface of the thermoelectric matrix; and
a nano-thermoelectric material disposed at an interface between the thermoelectric matrix and the nano metal particle,
wherein the nano-thermoelectric material is represented by Formula 1:
AₓM_{y}B_{z} Formula 1
wherein
A comprises at least one element of indium, bismuth, or antimony,
B comprises at least one element of tellurium and selenium,
M comprises at least one element of gallium, thallium, lead, rubidium, sodium, or lithium,
x is greater than 0 and less than or equal to about 4,
y is greater than 0 and less than or equal to about 4, and
z is greater than 0 and less than or equal to about 3.

12. A thermoelectric element comprising the thermoelectric nano-composite of claim 1.

13. A thermoelectric module comprising:
a first electrode;
a second electrode; and
the thermoelectric element of claim 12, wherein the thermoelectric element is disposed between the first electrode and the second electrode.

14. A thermoelectric apparatus comprising:
a heat supply source; and
a thermoelectric module comprising:
a thermoelectric element which absorbs heat from the heat supply source, and
the thermoelectric nano-composite of claim 1;
a first electrode contacting the thermoelectric element; and
a second electrode facing the first electrode and contacting the thermoelectric element.

15. A method of preparing a thermoelectric nano-composite, the method comprising:
contacting a thermoelectric matrix and a nano-sized metal particle to form a combination; and
sintering the combination under pressure,
wherein
the thermoelectric matrix comprises at least one element of indium, bismuth, or antimony, and at least one element of tellurium or selenium, and
the nano-sized metal particle comprises at least one element of gallium, thallium, lead, rubidium, sodium, or lithium.

16. The method of claim 15, wherein the contacting is any one of
mixing the thermoelectric matrix with a metal precursor,
spraying a solution comprising a metal precursor dissolved in an organic solvent on the thermoelectric matrix, or
dissolving the thermoelectric matrix and the metal precursor in an organic solvent and then performing a solvothermal method which comprises irradiating the organic solvent with a microwave.
